(19) United States
(12) Patent Application Publication
(10) Pub. No.: US 2013/0052790 A1
(43) Pub. Date: Feb. 28, 2013

(54) DOPING APPROACH OF TITANIUM DIOXIDE FOR DRAM CAPACITORS

(71) Applicants: Wim Deweerd, San Jose, CA (US); Hanhong Chen, San Jose, CA (US); Hiroyuki Ode, Hiroshima (JP)

(72) Inventors: Wim Deweerd, San Jose, CA (US); Hanhong Chen, San Jose, CA (US); Hiroyuki Ode, Hiroshima (JP)

(73) Assignees: ELPIDA MEMORY, INC., Tokyo (JP); INTERMOLECULAR, INC., San Jose, CA (US)

(21) Appl. No.: 13/219,870

(22) Filed: Aug. 29, 2011

(51) Int. Cl. H01L 21/02

(52) U.S. Cl. 438/396; 257/E21.008

(57) ABSTRACT

A method for fabricating a DRAM capacitor stack is described wherein the dielectric material is a doped material formed from a first dopant in concert with a second dopant wherein the second dopant has a different physical size from the first dopant and the presence of the second dopant influences the solubility of the first dopant in the dielectric material. The dielectric material maintains a high k-value while minimizing the leakage current and the EOT value

This document relates to the subject matter of a joint research agreement between Intermolecular, Inc. and Elpida Memory, Inc.

### FIELD OF THE INVENTION

The present invention generally relates to the field of dynamic random access memory (DRAM), and more particularly to dielectric material processing for improved DRAM performance.

### BACKGROUND OF THE INVENTION

Dynamic Random Access Memory utilizes capacitors to store bits of information within an integrated circuit. A capacitor is formed by placing a dielectric material between two electrodes formed from conductive materials. A capacitor's ability to hold electrical charge (i.e., capacitance) is a function of the surface area of the capacitor plates A, the distance between the capacitor plates d (i.e. the physical thickness of the dielectric layer), and the relative dielectric constant or k-value of the dielectric material. The capacitance is given by:

$$C = {κɛ}_{o} \frac{A}{d} \qquad ( Eqn . 1 )$$

where ∈₀ represents the vacuum permittivity.

The dielectric constant is a measure of a material's polarizability. Therefore, the higher the dielectric constant of a material, the more charge the capacitor can hold. Therefore, if the k-value of the dielectric is increased, the area of the capacitor can be decreased and maintain the desired cell capacitance. Reducing the size of capacitors within the device is important for the miniaturization of integrated circuits. This allows the packing of millions (mega-bit (Mb)) or billions (giga-bit (Gb)) of memory cells into a single semiconductor device. The goal is to maintain a large cell capacitance (generally ˜10 to 25 fF) and a low leakage current (generally <10⁻⁷ A cm⁻²). The physical thickness of the dielectric layers in DRAM capacitors could not be reduced unlimitedly in order to avoid leakage current caused by tunneling mechanisms which exponentially increases as the thickness of the dielectric layer decreases.

Traditionally, SiO₂ has been used as the dielectric material and semiconducting materials (semiconductor-insulator-semiconductor [SIS] cell designs) have been used as the electrodes. The cell capacitance was maintained by increasing the area of the capacitor using very complex capacitor morphologies while also decreasing the thickness of the SiO₂ dielectric layer. Increases of the leakage current above the desired specifications have demanded the development of new capacitor geometries, new electrode materials, and new dielectric materials. Cell designs have migrated to metal-insulator-semiconductor (MIS) and now to metal-insulator-metal (MIM) cell designs for higher performance.

One class of high-k dielectric materials possessing the characteristics required for implementation in advanced DRAM capacitors are high-k metal oxide materials. Examples of suitable dielectric materials comprise SiO₂, a bilayer of SiO₂ and SiₓN_{y}, SiON, Al₂O₃, HfO₂, HfSiOₓ, ZrO₂, Ta₂O₅, TiO₂, SrTiO₃ (STO), BaSrTiOₓ (BST), PbZrTiOₓ (PZT), etc. TiO₂ and ZrO₂ are two specific examples of metal oxide dielectric materials which display significant promise in terms of serving as a high-k dielectric material for implementation in DRAM capacitors.

Typically, DRAM devices at technology nodes of 80 nm and below use MIM capacitors wherein the electrode materials are metals. These electrode materials generally have higher conductivities than the semiconductor electrode materials, higher work functions, exhibit improved stability over the semiconductor electrode materials, and exhibit reduced depletion effects. The electrode materials must have high conductivity to ensure fast device speeds. Representative examples of electrode materials for MIM capacitors are metals, conductive metal oxides, conductive metal silicides, conductive metal nitrides (i.e. TiN), or combinations thereof. MIM capacitors in these DRAM applications utilize insulating materials having a dielectric constant, or k-value, significantly higher than that of SiO₂ (k=3.9). For DRAM capacitors, the goal is to utilize dielectric materials with k values greater than about 40. Such materials are generally classified as high-k materials. Representative examples of high-k materials for MIM capacitors are non-conducting metal oxides, non-conducting metal nitrides, non-conducting metal silicates or combinations thereof. These dielectrics may also include additional dopant materials.

A figure of merit in DRAM technology is the electrical performance of the dielectric material as compared to SiO₂ known as the Equivalent Oxide Thickness (EOT). A high-k material's EOT is calculated using a normalized measure of silicon dioxide (SiO₂ k=3.9) as a reference, given by:

$$EOT = \frac{3.9}{κ} \cdot d \qquad ( Eqn . 2 )$$

where d represents the physical thickness of the capacitor dielectric.

As DRAM technologies scale below the 40 nm technology node, manufacturers must reduce the EOT of the high-k dielectric films in MIM capacitors in order to increase charge storage capacity. The goal is to utilize dielectric materials that exhibit an EOT of less than about 0.8 nm while maintaining a physical thickness of about 5-20 nm.

Generally, as the dielectric constant of a material increases, the band gap of the material decreases. For example. The rutile phase of TiO₂ has a k-value of about 80 and a band gap of about 3.0 eV while ZrO₂ in the tetragonal phase has a k-value of about 43 and a band gap of about 5.8 eV. The low band gap may lead to high leakage current in the device. As a result, without the utilization of countervailing measures, capacitor stacks implementing high-k dielectric materials may experience large leakage currents. High work function electrodes (e.g., electrodes having a work function of greater than 5.0 eV) may be utilized in order to counter the effects of implementing a reduced band gap high-k dielectric layer within the DRAM capacitor. Metals, such as platinum, gold, ruthenium, and ruthenium oxide are examples of high work function electrode materials suitable for inhibiting device leakage in a DRAM capacitor having a high-k dielectric layer. The noble metal systems, however, are prohibitively expensive when employed in a mass production context. Moreover, electrodes fabricated from noble metals often suffer from poor manufacturing qualities, such as surface roughness, poor adhesion, and form a contamination risk in the fab.

Leakage current in capacitor dielectric materials can be due to Schottky emission, Frenkel-Poole defects (e.g. oxygen vacancies (Vₒₓ) or grain boundaries), or Fowler-Nordheim tunneling. Schottky emission, also called thermionic emission, is a common mechanism and is the thermally activated flow of charge over an energy barrier whereby the effective barrier height of a MIM capacitor controls leakage current. The nominal barrier height is a function of the difference between the work function of the electrode and the electron affinity of the dielectric. The electron affinity of a dielectric is closely related to the conduction band offset of the dielectric. The Schottky emission behavior of a dielectric layer is generally determined by the properties of the dielectric/electrode interface. Frenkel-Poole emission allows the conduction of charges through a dielectric layer through the interaction with defect sites such as vacancies, grain boundaries, and the like. As such, the Frenkel-Poole emission behavior of a dielectric layer is generally determined by the dielectric layer's bulk properties. Fowler-Nordheim emission allows the conduction of charges through a dielectric layer through direct tunneling without any intermediary interaction with e.g. defects. As such, the Fowler-Nordheim emission behavior of a dielectric layer is generally determined by the physical thickness of the dielectric layer. This leakage current is a primary driving force in the adoption of high-k dielectric materials. The use of high-k materials allows the physical thickness of the dielectric layer to be as thick as possible while maintaining the required capacitance (see Eqn 1 above).

High k metal oxide materials generally possess a number of defects in the form of oxygen vacancies. As an example, TiO₂ is well known to exhibit n-type material properties due to the presence of oxygen vacancies. The defects contribute trap states within the band gap of the material and increase the leakage current due to the Frenkel-Poole emission mechanism discussed previously. Also, the carrier density is increased since the oxygen vacancies also act as donors. Annealing the dielectric material in an oxidizing atmosphere after deposition will improve the leakage current; however, oxygen vacancies will still be present. One method for further decreasing the leakage current in high k dielectric materials is to add dopants to the material to compensate the carriers generated from the defects or vacancies. As an example, since TiO₂ is an n-type material, acceptor dopants such as Al and Ge are often used to decrease the leakage current. These dopants are trivalent and neutralize the free carriers generated by the oxygen vacancies. They are believed to be substitutional donors for Ti when added to the TiO₂. However, Al and Ge are small atoms, have limited solubility in TiO₂, and their incorporation distorts the TiO₂ matrix. Even after doping the TiO₂ with Al or Ge, at elevated temperatures, free carriers again become available and the leakage current increases. Therefore, there is a need to develop methods for decreasing the leakage current in MIM DRAM capacitors at high temperatures while maintaining a high k vale and a low EOT.

### SUMMARY OF THE INVENTION

In some embodiments of the present invention, a first dopant is added to the dielectric material to decrease the leakage current in MIM DRAM capacitors. Advantageously, the first dopant is selected to have an ionic radius that is smaller than that of the metal atom in the base dielectric material. A second dopant which has an ionic radius that is larger in size than that of the first dopant is also added to the dielectric material to further reduce the leakage current by adding additional carrier compensation capacity and by relieving the strain on the dielectric matrix induced by the first dopant and increase the polarization of the high k dielectric matrix. This may also have the benefit of reducing the EOT. Advantageously, the second dopant is selected to have an ionic radius that is larger than that of the metal atom in the base dielectric material. In some embodiments of the present invention, the dielectric material is TiO₂, the first dopant is one of Al or Ge, and the second dopant is one of Ga, Y, La, Zr, Hf, Sc, Nd, Ce, In, Sn, Er, Gd, Mg, Mn, Lu, Pr, or Co. In some embodiments of the present invention, the second dopant is chosen to fill the oxygen vacancies and substitute for the oxygen atoms in the matrix. Examples of this type of dopants comprise one of S, Se, Te, C, F, Cl, Br, I, P, As, Sb, and Bi.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a flow chart illustrating a method for fabricating a DRAM capacitor stack, in accordance with some embodiments of the present invention.

FIG. 2 illustrates a simplified cross-sectional view of a DRAM capacitor stack fabricated in accordance with some embodiments of the present invention.

FIG. 3 presents data illustrating the leakage current as a function of Al atomic % for a number of co-doped dielectric films according to some embodiments herein.

FIG. 4 presents data illustrating the leakage current as a function of EOT for a number of co-doped dielectric films according to some embodiments herein.

FIG. 5 illustrates a simplified cross-sectional view of a DRAM memory cell fabricated in accordance with some embodiments of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The dielectric constant of a dielectric material may be dependent upon the crystalline phase(s) of the material. For example, in the case of TiO₂, the anatase crystalline phase of TiO₂ has a dielectric constant of approximately 40, while the rutile crystalline phase of TiO₂ can have a dielectric constant of approximately >80. Due to the higher-k value of the rutile-phase, it is desirable to produce TiO₂ based DRAM capacitors with the TiO₂ in the rutile-phase. The relative amounts of the anatase phase and the rutile phase can be determined from x-ray diffraction (XRD). From Eqn. 1 above, a TiO₂ layer in the rutile-phase could be physically thicker and maintain the same desired capacitance as a TiO₂ layer in the anatase-phase. The increased physical thickness is important for lowering the leakage current of the capacitor. The anatase phase will transition to the rutile phase at high temperatures (>8000). However, high temperature processes are undesirable in the manufacture of DRAM devices. Traditional annealing processes may degrade the underlying electrode due to oxidation or promote interaction between the TiO₂ and the electrode material. The degradation may lead to an increase in the EOT and/or increased device leakage.

The crystal phase of an underlying layer can be used to influence the growth of a specific crystal phase of a subsequent material if their crystal structures are similar and their lattice constants are similar. This technique is well known in technologies such as epitaxial growth. The same concepts have been extended to the growth of thin films where the underlying layer can be used as a “template” to encourage the growth of a desired phase over other competing crystal phases.

Conductive metal oxides, conductive metal silicides, conductive metal nitrides, or combinations thereof comprise other classes of materials that may be suitable as DRAM capacitor electrodes. Generally, transition metals and their conductive binary compounds form good candidates as electrode materials. The transition metals exist in several oxidation states. Therefore, a wide variety of compounds are possible. Different compounds may have different crystal structures, electrical properties, etc. It is important to utilize the proper compound for the desired application.

In one example, molybdenum has several binary oxides of which MoO₂ and MoO₃ are two examples. These two oxides of molybdenum have different properties. MoO₂ is conductive and has shown great promise as an electrode material in DRAM capacitors. MoO₂ has a distorted rutile crystal structure and can serve as an acceptable template to promote the deposition of the rutile-phase of TiO₂ as discussed above. MoO₂ also has a high work function (can be >5.0 eV depending on process history) which helps to minimize the leakage current of the DRAM device. However, oxygen-rich phases (MoO₂₊ₓ) of MoO₂ degrade the performance of the MoO₂ electrode because they act more like insulators and have crystal structures that do not promote the deposition of the rutile-phase of TiO₂. For example, MoO₃ (the most oxygen-rich phase) is a dielectric material and has an orthorhombic crystal structure.

Generally, a deposited thin film may be amorphous, crystalline, or a mixture thereof after the deposition process. Furthermore, several different crystalline phases may exist. Therefore, processes (both deposition and post-treatment) must be developed to maximize the formation of the desired crystalline phases. Undesirable phases may form during the deposition of the electrode and may not be evenly distributed throughout the layer thickness. The electrode material may be deposited using any common deposition technique such as atomic layer deposition (ALD), plasma enhanced atomic layer deposition (PE-ALD), atomic vapor deposition (AVD), ultraviolet assisted atomic layer deposition (UV-ALD), chemical vapor deposition (CVD), plasma enhanced chemical vapor deposition (PECVD), or physical vapor deposition (PVD). Typically, the electrode material must be annealed after deposition to crystallize the film.

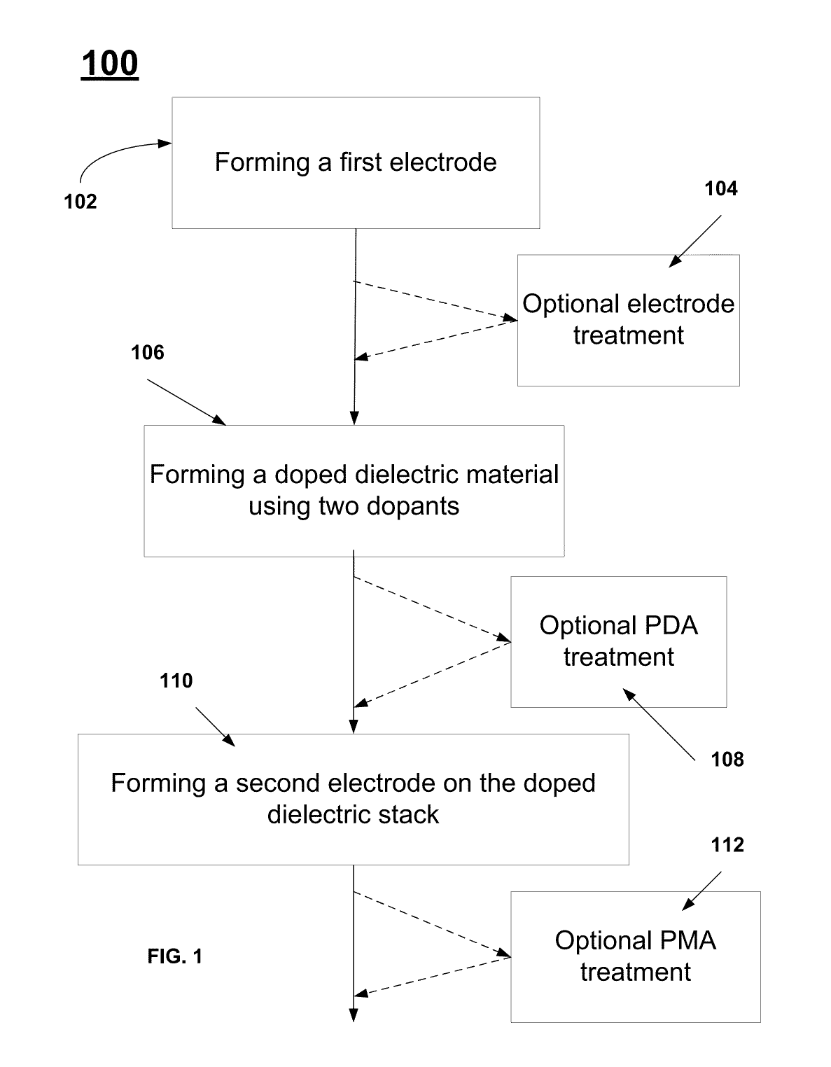

FIG. 1 illustrates a method, 100, for forming a DRAM capacitor stack in accordance with some embodiments of the present invention. The initial step, 102, comprises forming a first electrode layer on a substrate. Examples of suitable electrode materials comprise metals, conductive metal oxides, conductive metal silicides, conductive metal nitrides, and combinations thereof. A particularly interesting class of materials is the conductive metal oxides. Optionally, the first electrode layer can be subjected to an annealing or treatment process in step, 104. The annealing or treatment process will depend on the composition of the first electrode. If the first electrode is a metal such as TiN, then the treatment of the first electrode layer may include annealing using a Rapid Thermal Anneal (RTA) technique wherein the temperature is quickly raised in the presence of a nitrogen containing gas such as N₂, forming gas, NH₃, etc. Examples of such electrode treatment steps are further described in U.S. application Ser. No. 13/051,531 filed on Mar. 18, 2011, which is incorporated herein by reference. Optionally, the first electrode may be annealed in a reducing atmosphere. This is especially advantageous if the first electrode is a conductive metal oxide. One example of such an annealing process is further described in U.S. application Ser. No. 13/084,666 filed on Apr. 12, 2011, entitled “METHOD FOR FABRICATING A DRAM CAPACITOR” and is incorporated herein by reference.

Continuing with FIG. 1, in step 106, a doped high k material is formed by doping a high k material such as the rutile phase of TiO₂ with a first dopant comprising one of Al, or Ge. Al and Ge are acceptor-type dopants in TiO₂. Al and Ge have smaller ionic radii than Ti. A second dopant is added to the doped high k material to further reduce the leakage current. Examples of the second second dopant comprise one of Ga, Y, La, Zr, Hf, Sc, Nd, Ce, In, Sn, Er, Gd, Mg, Mn, Lu, Pr, or Co. The doped high k material may be formed as a hybrid stack or a nanolaminate stack. The second dopant is selected to have a valence of less than or equal to 4 and is selected to have an ionic radius larger than the first dopant. Advantageously, the ionic radius of the second dopant is also larger than the ionic radius of the metal atom in the base high k material. The valence of less than or equal to 4 ensures that the second dopant is also an acceptor-type dopant and can further neutralize free carriers generated by oxygen vacancies. Therefore, they will behave electrically in a similar manner to Al or Ge within the dielectric matrix. It is believed that the larger ionic radius will relieve some of the strain on the dielectric matrix induced by the first dopant. This may increase the solubility of the first dopant in the dielectric matrix.

Optionally, the dielectric layer can receive a post dielectric anneal (PDA) treatment in step 108. The PDA treatment serves to crystallize the dielectric layer and ensure that the material is fully oxidized. The next step, 110, comprises forming a second electrode layer on the doped high k material. The second electrode layer may be a conductive binary metal compound material as described above, a metal, or a combination thereof. The remaining full DRAM device (not shown) would then be manufactured using well known techniques. Optionally, the DRAM capacitor stack may undergo a post metallization anneal (PMA) treatment in step 112. Examples of the PDA treatment described above and the PMA treatment are further described in U.S. application Ser. No. 13/159,842 filed on Jun. 14, 2011, entitled “METHOD OF PROCESSING MIM CAPACITORS TO REDUCE LEAKAGE CURRENT” and is incorporated herein by reference.

Those skilled in the art will appreciate that each of the first electrode layer, the dielectric layer, and the bilayer second electrode structure (both bottom and top portions) used in the MIM DRAM capacitor may be formed using any common formation technique such as ALD, PE-ALD, AVD, UV-ALD, CVD, PECVD, or PVD. Generally, because of the complex morphology of the DRAM capacitor structure, ALD, PE-ALD, AVD, or CVD are preferred methods of formation. However, any of these techniques are suitable for forming each of the various layers discussed below. Those skilled in the art will appreciate that the teachings described below are not limited by the technology used for the deposition process.

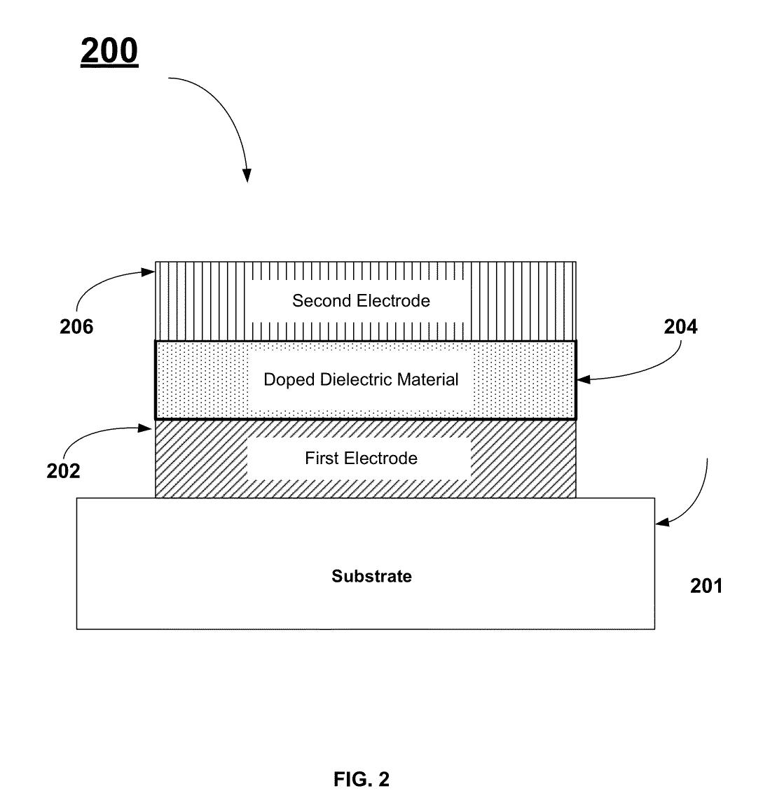

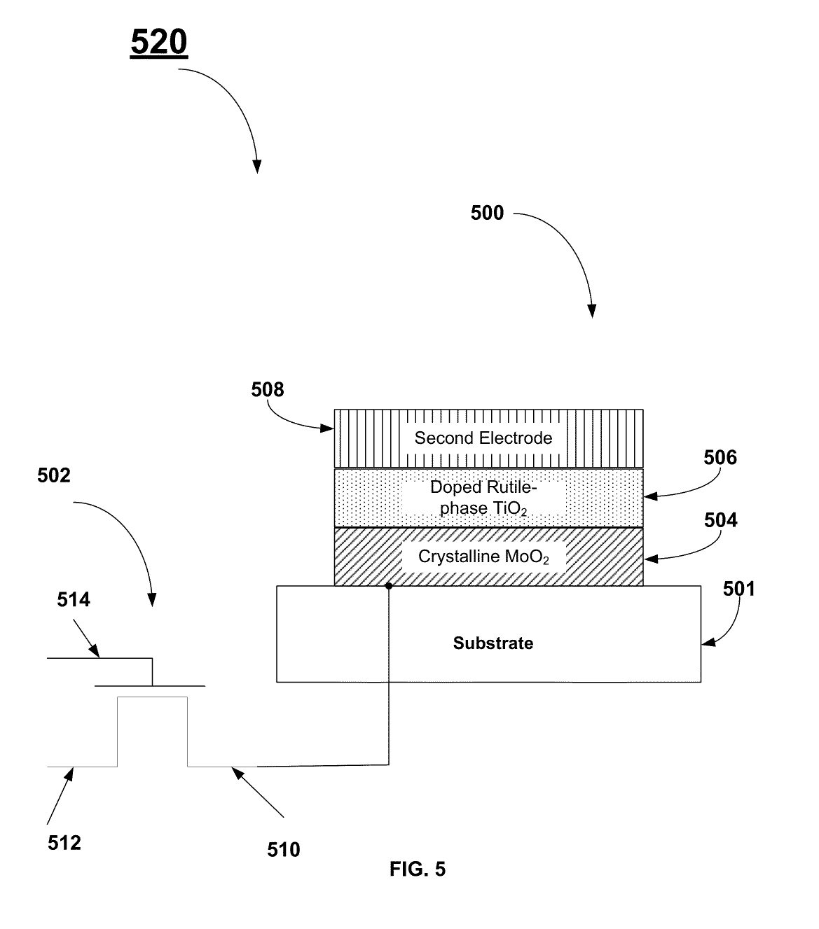

In FIGS. 2, and 5 below, a capacitor stack is illustrated using a simple planar structure. Those skilled in the art will appreciate that the description and teachings to follow can be readily applied to any simple or complex capacitor morphology. The drawings are for illustrative purposes only and do not limit the application of the present invention.

FIG. 2 illustrates a simple capacitor stack, 200, consistent with some embodiments of the present invention. Using the method as outlined in FIG. 1 and described above, first electrode layer, 202, is formed on substrate, 201. Generally, the substrate has already received several processing steps in the manufacture of a full DRAM device. First electrode layer, 202, comprises one of metals, conductive metal oxides, conductive metal nitrides, conductive metal silicides, etc. Optionally, first electrode, 202, can be annealed to crystallize the material.

In the next step, a doped high k material, 204, would then be formed on the annealed first electrode layer, 202 using two or more dopants as discussed previously. A wide variety of dielectric materials have been targeted for use in DRAM capacitors. Examples of suitable dielectric materials comprise SiO₂, a bilayer of SiO₂ and SiₓN_{y}, SiON, Al₂O₃, HfO₂, HfSiOₓ, ZrO₂, Ta₂O₅, TiO₂, SrTiO₃ (STO), BaSrTiOₓ (BST), PbZrTiOₓ (PZT), etc. A specific example of interest is doped versions of TiO₂. However, other doped high k materials may also yield the benefits discussed previously. The doped high k material may be formed as a single layer or may be formed as a hybrid or nanolaminate structure. Typically, doped high k material, 204, is subjected to a PDA treatment before the formation of the second electrode as discussed previously. The PDA treatment serves to crystallize the doped high k material and repair defects in the doped high k material.

Second electrode, 206, is then formed on doped high k material, 204. The second electrode is typically a metal such as TiN, TaN, TiAlN, W, WN, Mo, MoO₂, Mo₂N, Ru, doped-SnO₂, or others. Advantageously, the second electrode is TiN, MoO₂, Ru, or doped-SnO₂. Typically, the capacitor stack is then subjected to a PMA treatment as discussed previously.

An example of one embodiment will be described using FIG. 2 as a template. In a first step, a first electrode, 202, is formed on a substrate. Generally, the substrate has already received several processing steps in the manufacture of a full DRAM device. First electrode layer, 202, comprises one of metals, conductive metal oxides, conductive metal nitrides, conductive metal silicides, etc. For this example, first electrode layer, 202, comprises a conductive metal oxide that may serve to promote the rutile phase of TiO₂. Examples of such conductive metal oxides include the conductive compounds of molybdenum oxide, tungsten oxide, ruthenium oxide, iron oxide, iridium oxide, chromium oxide, manganese oxide, tin oxide, cobalt oxide, or nickel oxide. A specific electrode material of interest is the crystalline MoO₂ compound of molybdenum dioxide.

Optionally, first electrode, 202, can be annealed to crystallize the material. In the case of crystalline MoO₂, it is advantageous to anneal the first electrode in a reducing atmosphere to prevent the formation of oxygen-rich compounds as discussed earlier.

In the next step, doped high k material, 204, would then be formed on the annealed first electrode layer, 202. A wide variety of dielectric materials have been targeted for use in DRAM capacitors. Examples of suitable dielectric materials comprise SiO₂, a bilayer of SiO₂ and SiₓN_{y}, SiON, Al₂O₃, HfO₂, HfSiOₓ, ZrO₂, Ta₂O₅, TiO₂, SrTiO₃ (STO), BaSrTiO, (BST), PbZrTiO, (PZT), etc. A specific example of interest is doped TiO₂. The doped TiO₂ material will contain a first dopant of an element comprising one of Al, or Ge. The first dopant is present in the range from about 0 atomic % to about 15 atomic % and advantageously in the range between about 6 atomic % and about 10 atomic %. The doped TiO₂ material will also contain a second dopant of an element comprising one of Ga, Y, La, Zr, Hf, Sc, Nd, Ce, In, Sn, Er, Gd, Mg, Mn, Lu, Pr, or Co. The second dopant is advantageously present in the range from about 0 atomic % to about 15 atomic %. These doped TiO₂ materials may be formed as a single layer or may be formed as a hybrid or nanolaminate structure. Typically, the doped TiO₂ material, 204, is subjected to a PDA treatment before the formation of the second electrode as discussed previously.

Second electrode, 206, is then formed on the doped TiO₂ material, 204. The second electrode is typically a metal such as TiN, TaN, TiAlN, W, WN, Mo, MoO₂, Mo₂N, Ru, doped-SnO₂, or others. Advantageously, the second electrode is TiN, MoO₂, Ru, or doped-SnO₂. The second electrode is typically between about 5 nm and 50 nm in thickness. Typically, the capacitor stack is then subjected to a PMA treatment as discussed previously.

A second example of one embodiment will be described, also using FIG. 2 as a template. In a first step, a first electrode, 202, is formed on a substrate. Generally, the substrate has already received several processing steps in the manufacture of a full DRAM device. First electrode layer, 202, comprises one of metals, conductive metal oxides, conductive metal nitrides, conductive metal silicides, etc. For this example, first electrode layer, 202, comprises a conductive metal oxide that may serve to promote the rutile phase of TiO₂. Examples of such conductive metal oxides include the conductive compounds of molybdenum oxide, tungsten oxide, ruthenium oxide, iron oxide, iridium oxide, chromium oxide, manganese oxide, tin oxide, cobalt oxide, or nickel oxide. A specific electrode material of interest is the crystalline MoO₂ compound of molybdenum dioxide.

Optionally, first electrode, 202, can be annealed to crystallize the material. In the case of crystalline MoO₂, it is advantageous to anneal the first electrode in a reducing atmosphere to prevent the formation of oxygen-rich compounds as discussed earlier.

In the next step, doped high k material, 204, would then be formed on the annealed first electrode layer, 202. A wide variety of dielectric materials have been targeted for use in DRAM capacitors. Examples of suitable dielectric materials comprise SiO₂, a bilayer of SiO₂ and SiₓN_{y}, SiON, Al₂O₃, HfO₂, HfSiOₓ, ZrO₂, Ta₂O₅, TiO₂, SrTiO₃ (STO), BaSrTiOₓ (BST), PbZrTiOₓ (PZT), etc. A specific example of interest is doped TiO₂. The doped TiO₂ material will contain a first dopant of an element comprising one of Al, or Ge. The first dopant is present in the range from about 0 atomic % to about 15 atomic % and advantageously in the range between about 6 atomic % and about 10 atomic %. The doped TiO₂ material will also contain a second dopant of an element comprising one of S, Se, Te, C, F, Cl, Br, I, P, As, Sb, and Bi. The second dopant is advantageously present in the range from about 0 atomic % to about 30 atomic %. The mechanism for leakage current reduction is different for this group of dopants. In this example, the second dopant is selected to be substitutional for the oxygen in the TiO₂ matrix and is expected to fill the oxygen vacancies, thus reducing the leakage current. These doped TiO₂ materials may be formed as a single layer or may be formed as a hybrid or nanolaminate structure. Typically, the doped TiO₂ material, 204, is subjected to a PDA treatment before the formation of the second electrode as discussed previously.

Second electrode, 206, is then formed on the doped TiO₂ material, 204. The second electrode is typically a metal such as TiN, TaN, TiAlN, W, WN, Mo, MoO₂, Mo₂N, Ru, doped-SnO₂, or others. Advantageously, the second electrode is TiN, MoO₂, Ru, or doped-SnO₂. The second electrode is typically between about 5 nm and 50 nm in thickness. Typically, the capacitor stack is then subjected to a PMA treatment as discussed previously.

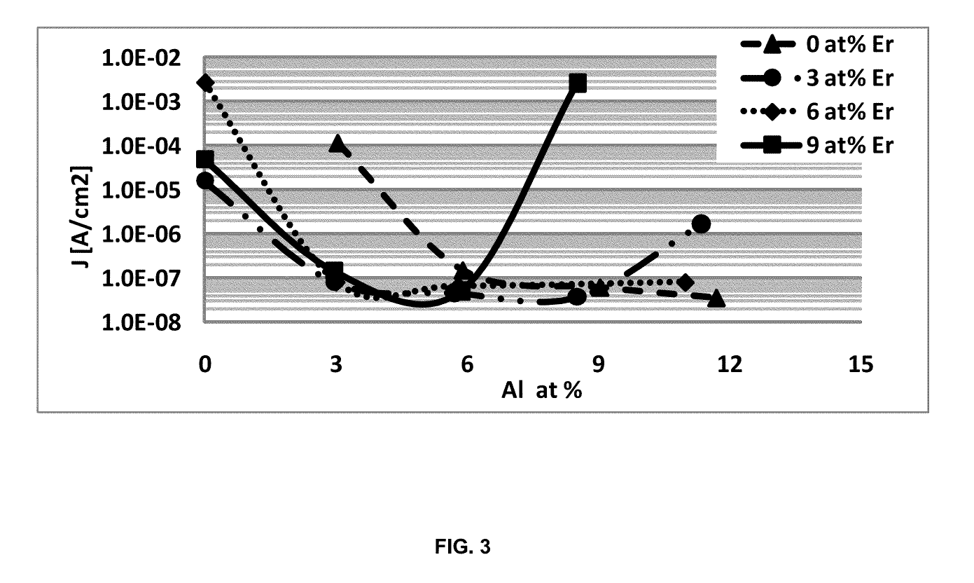

FIG. 3 presents data illustrating the leakage current as a function of Al atomic % for a number of co-doped dielectric films according to some embodiments herein. TiO₂ dielectric films were doped with Al in the range from O atomic % to about 12 atomic %. These films were further doped with Er in the range from O atomic % to about 9 atomic %. The baseline data with O atomic % Er are the triangles. The leakage current for TiO₂ films doped with only Al increases significantly below about 3 atomic % Al. The data indicate that when Er is added to the film, that less Al is required to reach low leakage levels. For example, all of the three films co-doped with Er exhibit leakage levels of less than about 2×10⁻⁷ A/cm² at Al doping levels of about 3 atomic %.

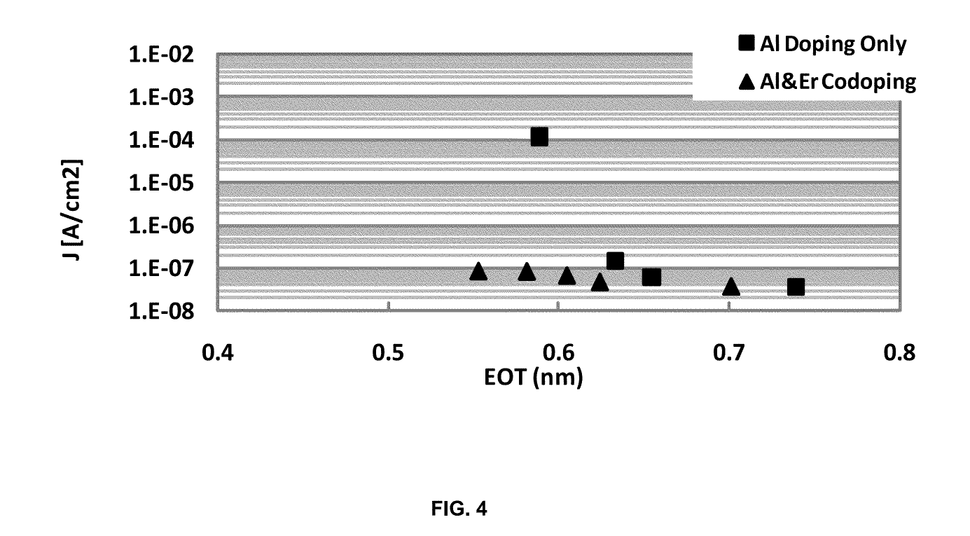

FIG. 4 presents data illustrating the leakage current as a function of EOT for a number of co-doped dielectric films according to some embodiments herein. TiO₂ dielectric films were doped with Al or co-doped with Al and Er. The baseline data with O atomic % Er are the squares. The leakage current for TiO₂ films doped with only Al increases significantly below an EOT of about 0.63 nm. The data indicate that when Er is added to the film, leakage levels of less than about 1×10⁻⁷ A/cm² can be achieved at EOT levels down to at least 0.55 nm.

An example of a specific application of some embodiments of the present invention is in the fabrication of capacitors used in the memory cells in DRAM devices. DRAM memory cells effectively use a capacitor to store charge for a period of time, with the charge being electronically “read” to determine whether a logical “one” or “zero” has been stored in the associated cell. Conventionally, a cell transistor is used to access the cell. The cell transistor is turned “on” in order to store data on each associated capacitor and is otherwise turned “off” to isolate the capacitor and preserve its charge. More complex DRAM cell structures exist, but this basic DRAM structure will be used for illustrating the application of this disclosure to capacitor manufacturing and to DRAM manufacturing. FIG. 5 is used to illustrate one DRAM cell, 520, manufactured using a doped high k material as discussed previously. The cell, 520, is illustrated schematically to include two principle components, a cell capacitor, 500, and a cell transistor, 502. The cell transistor is usually constituted by a MOS transistor having a gate, 514, source, 510, and drain, 512. The gate is usually connected to a word line and one of the source or drain is connected to a bit line. The cell capacitor has a lower or storage electrode and an upper or plate electrode. The storage electrode is connected to the other of the source or drain and the plate electrode is connected to a reference potential conductor. The cell transistor is, when selected, turned “on” by an active level of the word line to read or write data from or into the cell capacitor via the bit line.

As was described previously in connection with FIG. 2, the cell capacitor, 500, comprises a first electrode, 504, formed on substrate, 501. The first electrode, 504, is connected to the source or drain of the cell transistor, 502. For illustrative purposes, the first electrode has been connected to the source, 510, in this example. For the purposes of illustration, first electrode, 504, will be crystalline MoO₂ in this example. As discussed previously, first electrode, 504, may be subjected to an anneal in a reducing atmosphere before the formation of the dielectric layer to crystallize the MoO₂ and to reduce any MoO₂₊ₓ compounds that may have formed during the formation of the first electrode. Doped high k material, 506, is formed on top of the first electrode. For the purposes of illustration, doped high k material, 306, will be TiO₂ doped with Al and a second dopant comprising one of Ga, Y, La, Zr, Hf, Sc, Nd, Ce, In, Sn, Er, Gd, Mg, Mn, Lu, Pr, or Co. Alternatively, doped high k material, 506, will be TiO₂ doped with Al and a second dopant comprising one of S, Se, Te, C, F, Cl, Br, I, P, As, Sb, and Bi. Typically, the doped TiO₂ material is then subjected to a PDA treatment. The second electrode, 508, is then formed on top of the doped TiO₂ material. For the purposes of illustration, the second electrode, 508, will be TiN, MoO₂, Ru, or doped-SnO₂ in this example. This completes the formation of the capacitor stack. Typically, the capacitor stack is then subjected to a PMA treatment.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a capacitor stack comprising:
forming a first electrode layer on a substrate;
forming a dielectric layer on the first electrode layer wherein the dielectric layer comprises a dielectric material, the dielectric material further comprising a first dopant and a second dopant, wherein each of the dielectric material, the first dopant and the second dopant comprise a metal atom and wherein the metal atom of the first dopant has an ionic radius that is smaller than that of the metal atom of the dielectric material and wherein the metal atom of the first dopant has an ionic radius that is smaller than that of the metal atom of the second dopant; and
forming a second electrode layer on the dielectric layer.

2. The method of claim 1 wherein the dielectric material is one of SiO₂, a bilayer of SiO₂ and SiₓN_{y}, SiON, Al₂O₃, HfO₂, HfSiOₓ, ZrO₂, Ta₂O₅, TiO₂, SrTiO₃ (STO), BaSrTiOₓ (BST), or PbZrTiOₓ (PZT).

3. The method of claim 2 wherein the dielectric material is TiO₂.

4. The method of claim 1 wherein the metal atom of the dielectric material has an ionic radius that is smaller than that of the metal atom of the second dopant.

5. The method of claim 1 wherein the first dopant is an acceptor-type dopant in the dielectric material.

6. The method of claim 1 wherein the first dopant is one of Al or Ge.

7. The method of claim 1 wherein the first dopant is present at a concentration between about 0 atomic % and about 15 atomic %.

8. The method of claim 7 wherein the first dopant is present at a concentration between about 6 atomic % and about 10 atomic %.

9. The method of claim 1 wherein the second dopant has a valence of less than or equal to 4.

10. The method of claim 1 wherein the second dopant is one of Ga, Y, La, Zr, Hf, Sc, Nd, Ce, In, Sn, Er, Gd, Mg, Mn, Lu, Pr, or Co.

11. The method of claim 10 wherein the second dopant is present at a concentration between about 0 atomic % and about 15 atomic %.

12. The method of claim 1 wherein the first electrode is a conductive compound of one molybdenum oxide, tungsten oxide, ruthenium oxide, iron oxide, iridium oxide, chromium oxide, manganese oxide, tin oxide, cobalt oxide, or nickel oxide.

13. The method of claim 12 wherein the first electrode is a conductive compound of molybdenum oxide.

14. The method of claim 1 wherein the second electrode is one of TiN, TaN, TiAlN, W, WN, Mo, MoO₂, Mo₂N, Ru, doped-SnO₂.

15. The method of claim 14 wherein the second electrode is one of TiN, MoO₂, Ru, or doped-SnO₂.

16. A method for forming a capacitor stack comprising:
forming a first electrode layer on a substrate;
forming a dielectric layer on the first electrode layer wherein the dielectric layer comprises a dielectric material, the dielectric material further comprising a first dopant and a second dopant, wherein each of the dielectric material and the first dopant comprise a metal atom and wherein the metal atom of the first dopant has an ionic radius that is smaller than that of the metal atom of the dielectric material and wherein the second dopant is substitutional for an oxygen species of the dielectric material when the dielectric material is a metal oxide; and
forming a second electrode layer on the dielectric layer.

17. The method of claim 1 wherein the second dopant is one of S, Se, Te, C, F, Cl, Br, I, P, As, Sb, and Bi.

18. The method of claim 17 wherein the second dopant is present at a concentration between about 0 atomic % and about 30 atomic %.

19. The method of claim 16 wherein the dielectric material is one of SiO₂, a bilayer of SiO₂ and SiₓN_{y}, SiON, Al₂O₃, HfO₂, HfSiOₓ, ZrO₂, Ta₂O₅, TiO₂, SrTiO₃ (STO), BaSrTiOₓ (BST), or PbZrTiOₓ (PZT).

20. The method of claim 19 wherein the dielectric material is TiO₂.
